(19) United States
(12) Patent Application Publication
(10) Pub. No.: US 2026/0342284 A1
(43) Pub. Date: Oct. 29, 2026

(54) MULTIPHASE FREQUENCY MODULATION FOR REDUCED PEAK DEVIATION

(71) Applicant: QUALCOMM Incorporated, San Diego, CA (US)

(72) Inventors: Georgios MYLONAS, Cambourne (GB); Pravinkumar PREMAKANTHAN, Gilbert, AZ (US); Luis BRIONES, Chandler, AZ (US); Matthew COLLINS, Bradford on Avon (GB); Andrew Richard NORTH, Leicester (GB)

(21) Appl. No.: 19/107,791

(22) PCT Filed: Sep. 11, 2023
(86) PCT No.: PCT/US2023/073881

§ 371 Date: Feb. 28, 2025

(30) Foreign Application Priority Data
Sep. 14, 2022 (GR) 20220100752

(51) Int. Cl. H03C 3/20; H03C 5/00; H04L 27/36

(52) U.S. Cl. CPC H03C 3/20; H03C 5/00; H04L 27/36

(57) ABSTRACT

Aspects of the present disclosure provide techniques and apparatus for multiphase frequency modulation. An example method of multiphase frequency modulation includes determining a phase for a transmission signal based on a constellation point; determining an encoding for a frequency modulation based on the phase; generating a plurality of oscillating signals having different phases; effectively phase modulating the plurality of oscillating signals having the different phases, based on the encoding for the frequency modulation; and selecting one of the plurality of phase-modulated oscillating signals.

### CROSS-REFERENCE TO RELATED APPLICATION(S)

This application claims priority to Greece Patent Application No. 20220100752, filed Sep. 14, 2022, which is hereby incorporated by reference herein.

### BACKGROUND

### Field of the Disclosure

Certain aspects of the present disclosure generally relate to electronic circuits and, more particularly, to techniques and apparatus for frequency modulation.

### Description of Related Art

Electronic devices include traditional computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. Wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., IEEE 802.11), and the like. In some cases, a transmitter may be implemented as a polar transmitter, where in-phase/quadrature (I/Q) signals are converted to the polar domain as amplitude and phase components of a signal. The amplitude and phase components are then used to generate signals for transmission via a power amplifier.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide various advantages included reduced frequency modulation noise and improved wireless communication performance.

Certain aspects of the present disclosure provide transmitter circuit. The transmitter circuit generally includes a voltage-controlled oscillator (VCO) configured to generate an oscillating signal; a modulation digital-to-analog converter (MDAC) having an output coupled to a control input of the VCO and configured to effectively modulate a phase of the oscillating signal; a multiphase generator having an input coupled to an output of the VCO and configured to generate a plurality of oscillating signals having different phases from the phase-modulated oscillating signal; and a phase modulator having inputs coupled to outputs of the multiphase generator and configured to select and output one of the plurality of oscillating signals.

Certain aspects of the present disclosure provide a method of wireless communication. The method generally includes determining a phase for a transmission signal based on a constellation point; determining an encoding for a frequency modulation based on the phase; generating a plurality of oscillating signals having different phases; effectively phase modulating the plurality of oscillating signals having the different phases, based on the encoding for the frequency modulation; and selecting one of the plurality of phase-modulated oscillating signals.

Certain aspects of the present disclosure provide an apparatus for wireless communication. The apparatus generally includes means for determining a phase for a transmission signal based on a constellation point; means for determining an encoding for a frequency modulation based on the phase; means for generating a plurality of oscillating signals having different phases; means for effectively phase modulating the plurality of oscillating signals having the different phases, based on the encoding for the frequency modulation; and means for selecting one of the plurality of phase-modulated oscillating signals.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example polar transmitter.

FIG. 2 is a diagram illustrating an example of a transmitter circuit that uses multiphase frequency modulation.

FIG. 3 is a graph illustrating an example of multiple constellation points associated with oscillating signals generated using multiphase frequency modulation.

FIG. 4A is a graph illustrating an example of frequency modulations over time using a single frequency modulation.

FIG. 4B is a graph illustrating an example of frequency modulations over time using multiphase frequency modulation.

FIG. 5 is a flow diagram of example operations for wireless communication using multiphase frequency modulation.

FIG. 6 is a diagram of a wireless communication network that includes a wireless communication device configured to perform multiphase frequency modulation.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to methods and apparatus for multiphase frequency modulation.

Certain wireless communication devices (such as Bluetooth devices, IEEE 802.11 devices, and/or other or future radio access technologies) may use a polar transmitter, where in-phase/quadrature (I/Q) signals are converted to the polar domain as magnitude and phase components of a signal. As phase shifts can be accomplished by changing the frequency of a signal due to frequency being the reciprocal of a period, the phase component may be controlled using frequency modulation. The frequency modulation may be implemented via a voltage-controlled oscillator (VCO), where a digital-to-analog converter (DAC) may control the output frequency of the VCO. The DAC may control the frequency shifts in an oscillating signal generated by the VCO and may in effect create a phase shift of up to ±180 degrees, on the transmitted signal. In some cases, the frequency modulation may introduce noise into the phase component, for example, due to inaccuracies with the digital-to-analog conversion applied to the VCO and/or frequency shifts at the VCO, which may be caused by temperature drift, for example. Frequency modulation noise may translate to degraded wireless communication performance, such as increased adjacent channel power (e.g., increased self-interference or co-channel interference), increased latencies, and/or decreased data rates.

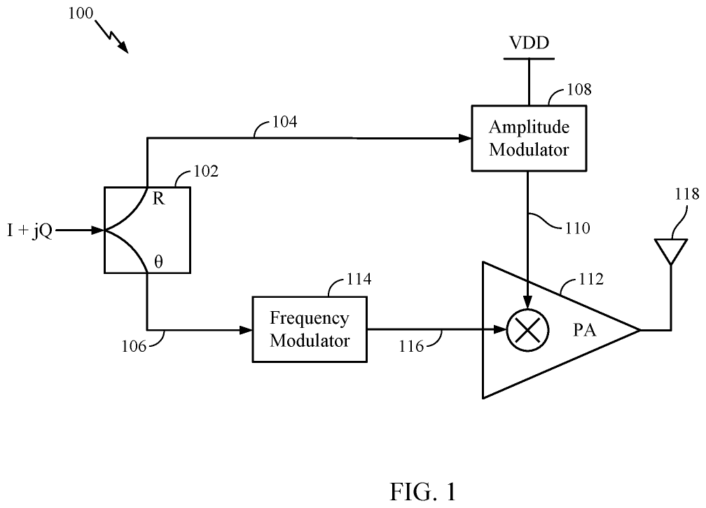

Certain aspects of the present disclosure provide methods and apparatus for multiphase frequency modulation, for example, for a polar transmitter. A wireless communications device (e.g., a Bluetooth device and/or IEEE 802.11 device) may include a polar transmitter, for example, in a transceiver (also referred to as a radio frequency front-end (RFFE) circuit or RF transceiver circuit) for transmitting and/or receiving RF signals. In certain cases, the polar transmitter may generate the phase component using multiple phase shift stages. For example, the VCO may be controlled to output a signal at a frequency corresponding to a fine phase shift (e.g., ±45 degrees), and the output signal may be phase modulated to generate multiple signals at phases corresponding to different coarse phase shifts (e.g., 0 degrees, 90 degrees, 180 degrees, and/or 270 degrees) relative to the output signal, as further described herein with respect to FIGS. 1-3.

The methods and apparatus for multiphase frequency modulation described herein may provide various advantages. The methods and apparatus described herein may improve the wireless communication performance of polar transmitters enabling reduced adjacent channel powers (e.g., reduced interference), decreased latencies, and/or increased data rates. The methods and apparatus described herein may reduce the frequency modulation noise, by reducing the maximum value of frequency modulation adjusted using a DAC. In some cases, the frequency modulation noise is reduced by 12 decibels, for example, and the reduction in frequency modulation noise may improve the wireless communication performance of the polar transmitter.

### Example RF Polar Transceiver

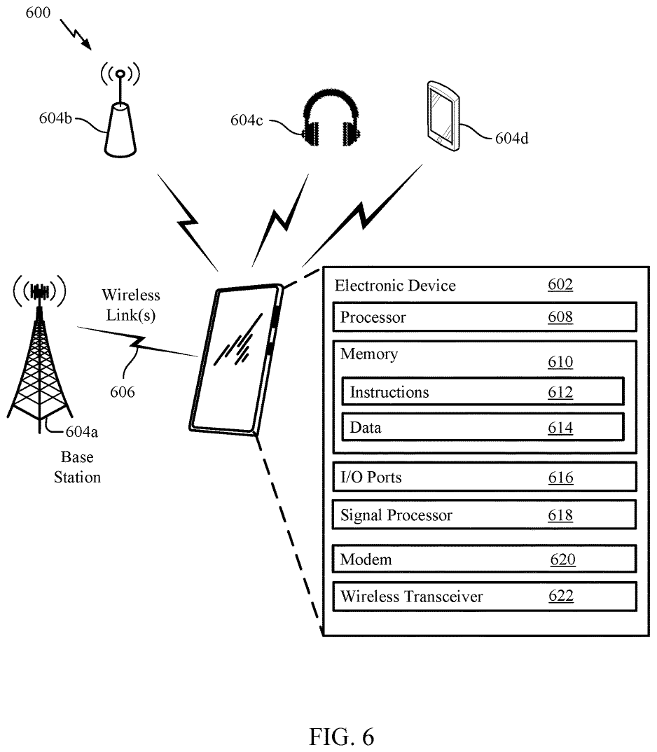

FIG. 1 is an example polar transmitter 100, which may be implemented in a transceiver front end, such as a wireless transceiver 622 as further described herein with respect to FIG. 6. The transceiver may use a baseband module for generating a baseband signal having in-phase (I) and quadrature (Q) components (I+jQ). The baseband signal may be provided to a polar processor 102, which may convert the baseband signal to the polar domain as a radius component 104 and a phase component 106, as illustrated. For example, assuming the baseband signal is a complex signal (I+jQ), the polar components may be determined as follows:

r=\sqrt{I²+Q²} (1a)

θ=arctan(Q/I) (1b)
where r is the radius component, and θ is the angular (phase) component. The radius component may correspond to an amplitude of a radio frequency signal, and the angular component may correspond to a phase of the radio frequency signal, where the phase may be converted to an instantaneous frequency. The radio frequency signal may be formed as a product of a radius signal and an oscillating signal (e.g., cos(t)) as follows:

s(t)=r(t)cos(2π·f_{c}·t+θ(t)) (2)
where s(t) is the transmitted radio frequency signal, r(t) is the radius signal representative of the radius component over time, f_{c} is the carrier frequency of the radio frequency signal, and θ(t) is the phase of the radio frequency signal and representative of the angular component over time. The radius signal may be formed as a series of amplitudes corresponding to the radius component in Expression (1a). Under a frequency modulation implementation, the phase signal may be formed as a series of frequency modulations, where each instantaneous frequency may correspond to a phase representative of the angular component in Expression (1b).

The radius component 104 (also referred to as a magnitude component) may be provided to an amplitude modulator 108. The amplitude modulator 108 generates a gain signal 110 (e.g., r(t)) and provides the gain signal 110 to a power amplifier (PA) 112. The gain signal 110 is indicative of an instantaneous power gain applied at the PA 112 to an input signal (e.g., cos(2π·f_{c}·t+θ(t))). The gain signal 110 may be representative of an instantaneous amplitude corresponding to the radius component 104.

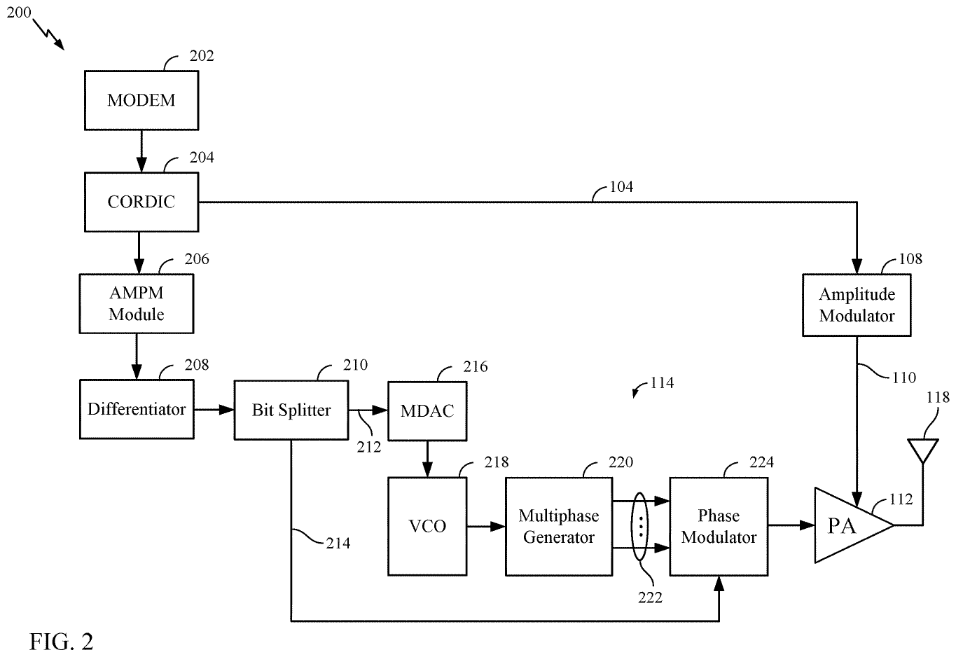

The phase component 106 is provided to a phase modulator, which, in some cases, may be implemented as a frequency modulator 114. The frequency modulator 114 generates a phase signal 116 at an instantaneous frequency that corresponds to a phase associated with the phase component 106. As further described herein with respect to FIG. 2, the frequency modulator 114 may use multiple stages of frequency modulation to generate the phase signal 116, which may reduce the noise produced by the frequency modulation and improve wireless communication performance, such as improved data rates. The phase signal 116 is effectively multiplied with the gain signal 110 using the PA 112 to generate a radio frequency signal (e.g., s(t)) at the output of the PA 112, which may be coupled to an antenna 118 that emits the radio frequency signal.

While FIG. 1 provides a polar transmitter as an example application in which certain aspects of the present disclosure may be implemented to facilitate understanding, certain aspects described herein related to multiphase frequency modulation may be utilized in various other suitable electronic systems.

### Example of Multiphase Frequency Modulation

FIG. 2 is a diagram of an example of a transmitter circuit 200 that uses multiphase frequency modulation. In this example, the transmitter circuit 200 may be a polar transmitter (e.g., the polar transmitter 100) having amplitude modulation circuitry (e.g., the amplitude modulator 108) and multiphase modulation circuitry (e.g., the frequency modulator 114).

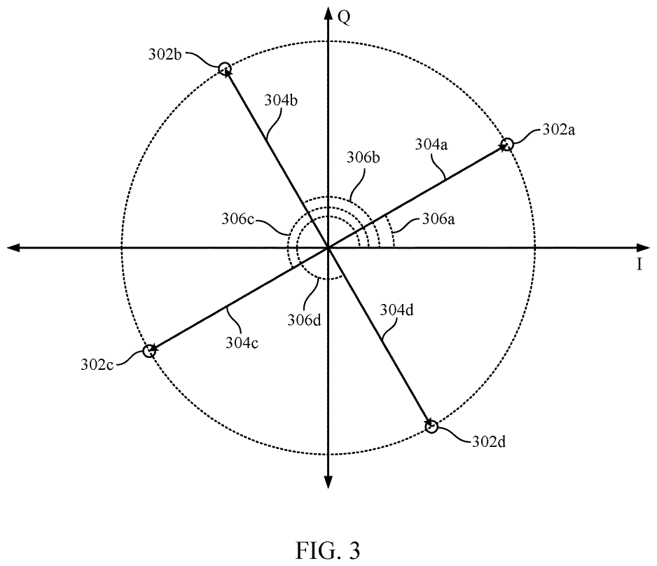

The transmit circuit 200 may include a modulator-demodulator (MODEM) 202 that modulates information into a complex signal (e.g., I(t)+jQ(t)), for example, as a series of complex symbols (e.g., I+jQ), which may correspond to constellation points, as further described herein with respect to FIG. 3. The MODEM 202 may provide the complex signal to a coordinate rotation digital computer (CORDIC) 204 that converts the complex signal into a radius component and an angular component in the polar domain, for example, according to the Expressions (1a) and (1b). The CORDIC 204 may provide the radius component and the angular component to an amplitude-modulation phase-modulation (AMPM) module 206. In some cases, the CORDIC 204 may provide the radius component to the amplitude modulator 108. The AMPM module 206 may determine the phase of the radio frequency signal based on the respective angular component and the radius component, for example, in order to adjust the angular component to compensate for AMPM distortion exhibited at the PA 112. For example, the AMPM module 206 may use a look-up table of radius component and angular component pairs associated with the corresponding phase to determine the instantaneous phase for the radio frequency signal. In some cases, the look-up table may provide the phase distortions at certain magnitudes, and the AMPM module 206 may determine the phase correction to compensate for the corresponding AMPM distortion using the look-up table. The AMPM module 206 may provide the phase to a differentiator 208.

The differentiator 208 may convert the phase into an instantaneous frequency having a period corresponding to the time delay of the phase. For example, the differentiator 208 may receive a phase encoding and convert the phase encoding into a frequency encoding based on the phase encoding using differentiation. The differentiator 208 may provide the encoding for frequency modulation to a bit splitter 210 (e.g., a frequency decoder). The differentiator 208 may have an output coupled to an input of the bit splitter 210.

The bit splitter 210 may include a frequency decoder that converts the frequency encoding into multiple frequency modulation components, such as a fine frequency modulation encoding 212 and a coarse frequency modulation encoding 214. The bit splitter 210 may provide the fine frequency modulation encoding 212 to a modulation digital-to-analog converter (MDAC) 216 and provide the coarse frequency modulation encoding 214 to a phase modulator 224. The bit splitter 210 may have a first output coupled to an input of the MDAC 216 and a second output coupled to a control input of the phase modulator 224.

The frequency modulator 114 may perform the phase modulation in multiple cascading stages. In a first phase modulation stage, the frequency modulator 114 may effectively perform a fine phase modulation, for example, using a voltage-controlled oscillator (VCO) 218, which generates an oscillating signal within a fine range of phases (e.g., ±45 degrees). In a second phase modulation stage, the frequency modulator 114 may effectively perform a coarse phase modulation that generates multiple oscillating signals at different phases (e.g., 0 degrees, 90 degrees, 180 degrees, and 270 degrees) from the oscillating signal output at the first phase modulation stage, and the frequency modulator 114 may select one of the oscillating signals with the coarse phase modulation. For example, the frequency modulator 114 may perform the coarse phase modulation using a multiphase generator 220, which generates multiple oscillating signals at different phases, and a phase modulator 224, which selects one of the oscillating signals, as further described herein.

The VCO 218 may generate an oscillating signal in response to a control signal output by the MDAC 216, which may have an output coupled to a control input of the VCO 218. In certain cases, the VCO 218 may be part of a phase-locked loop (PLL) circuit, such as a delta-sigma fractional-N phase-locked loop, used to control a tuning voltage of the VCO for controlling a frequency of the oscillating signal with respect to a reference clock. The MDAC 216 may effectively modulate a phase (e.g., ±45 degrees) of the oscillating signal output by the VCO 218 based on the control signal representing a frequency modulation associated with the fine frequency modulation encoding 212. In some cases, the MDAC 216 may output a control signal at a particular voltage that adjusts the output frequency of the VCO 218. In certain cases, the VCO 218 may be implemented as a resonator, for example, as an inductor-capacitor (LC) resonator, and the MDAC 216 may adjust the capacitance of the LC resonator to change the output frequency of the VCO 218.

Assuming the multiphase generator 220 generates a number (N) of the oscillating signals having the different phases, the MDAC 216 may control the VCO 218 to effectively modulate the phase of the oscillating signal by (±180/N)°. For example, the MDAC 216 may output the control signal at a particular voltage that causes the VCO 218 to output the oscillating signal at a frequency that corresponds to a phase associated with the fine frequency modulation encoding 212. The VCO 218 may provide the modulated oscillating signal to the multiphase generator 220. For example, the VCO 218 may have an output coupled to the multiphase generator 220.

The multiphase generator 220 may generate multiple oscillating signals 222 having different phases from the effectively-phase-modulated oscillating signal generated by the VCO 218. The multiphase generator 220 may have an input coupled to an output of the VCO 218, and the multiphase generator 220 may provide the oscillating signals to a phase modulator 224. The multiphase generator 220 may generate a number (N) of the oscillating signals having different phases, where the different phases are in increments of (360/N)°, and the VCO 218 may be controlled to effectively modulate the phase of the oscillating signal by (±180/N)°. For example, the multiphase generator 220 may generate four oscillating signals 222 with phase increments of 90° (e.g., 0 degrees, 90 degrees, 180 degrees, and 270 degrees), where a first oscillating signal corresponds to 0 degrees, a second oscillating signal corresponds to 90 degrees, a third oscillating signal corresponds to 180 degrees, and a fourth oscillating signal corresponds to 270 degrees. In such cases, the MDAC 216 may control the VCO 218 to effectively modulate the phase of the oscillating signal by ±45°.

The multiphase generator 220 may include one or more frequency dividers that output the oscillating signals 222 at different phases. For example, the multiphase generator 220 may have a frequency divider circuit that outputs an oscillating signal at 0 degrees (e.g., without a phase shift to the oscillating signal output by the VCO 218), outputs an oscillating signal at 90 degrees, outputs an oscillating signal at 180 degrees, and outputs an oscillating signal at 270 degrees. As an example, a divide-by-two frequency divider may generate I and Q components as well as inverted I and Q components such that the frequency divider outputs four phase (e.g., 0 degrees, 90 degrees, 180 degrees, and 270 degrees). It will be appreciated that a frequency divider is merely an example, and other circuitry may be used to generate oscillating signals at different phases, for example, time delay circuits.

The phase modulator 224 may select and output one of the plurality of oscillating signals 222 received from the multiphase generator 220. The coarse frequency modulation encoding 214 may control the selection of the one of the plurality of oscillating signals 222 by the phase modulator. For example, the coarse frequency modulation encoding 214 may indicate to the phase modulator 224 which of the oscillating signals 222 to select and output. In certain cases, the phase modulator 224 may include a multiplexer that selects an oscillating among the oscillating signals 222 for output. The phase modulator 224 may have inputs coupled to outputs of the multiphase generator 220. The phase modulator 224 may provide the selected oscillating signal to an amplifier, such as the PA 112.

The PA 112 may amplify the selected oscillating signal for transmission via the antenna 118. The PA 112 may have an input coupled to an output of the phase modulator and an output coupled to the antenna 118.

In some cases, the transmitter circuit 200 may include digital circuitry and/or analog circuitry. For example, the MODEM 202, CORDIC 204, AMPM module 206, differentiator 208, and the bit splitter 210 may be implemented as digital circuitry, such as a digital signal processor (DSP), a field programmable gate array (FPGA), a programmable logic device (PLD), discrete gate or transistor logic, or the like. The VCO 218 and the multiphase generator 220 may be implemented as analog circuitry.

FIG. 3 is a graph illustrating an example of multiple constellation points 302a-302d (collectively constellation points 302) associated with oscillating signals generated using multiphase frequency modulation as described herein. As used herein, a constellation point may represent a symbol of a signal as complex components (e.g., I+jQ) in a polar domain, where the angular component may correspond to the phase of the signal, and the radius component may correspond to the amplitude of the signal. The constellation points 302 represent one of the N constellation points that can be output using a multiphase frequency modulation and amplitude modulation of a polar transmitter, such as the transmitter circuit 200. For example, the radius components of the constellation points 302 are examples of a radio frequency signal after amplitude modulation is performed at the PA 112. Each of the constellation points 302 may have a corresponding radius component 304a-304d and a corresponding angular component 306a-306d. The first constellation point 302a may have a first radius component 304a and a first angular component 306a; the second constellation point 302b may have a second radius component 304b and a second angular component 306b; and so on for the other constellation points 302c, 302d.

In this example, as one of the coarse phase modulations may apply a zero degree phase, the first constellation point 302a may effectively represent the fine phase modulation applied using the VCO 218, and the other constellation points 302b-302d may represent the coarse phase modulation applied using the multiphase generator 220. For example, the first angular component 306a may be 30 degrees, and the other angular components 304b-304d may be in 90 degree increments from 30 degrees (e.g., 120 degrees, 210 degrees, and 300 degrees, respectively). The phase modulator 224 may select one of the oscillating signals to output one of the constellation points 302 associated with the corresponding phase component of the complex signal for transmission, for example, determined at the CORDIC 204 and/or AMPM module 206. In this manner with both fine and coarse frequency modulation, the phase component of any desired constellation point of a complex signal for transmission may be achieved. It will be appreciated that four constellation points are merely an example, and the multiphase frequency modulation described herein may generate two or more oscillating signals at different phases corresponding to two or more constellation points (e.g., >4 constellation points).

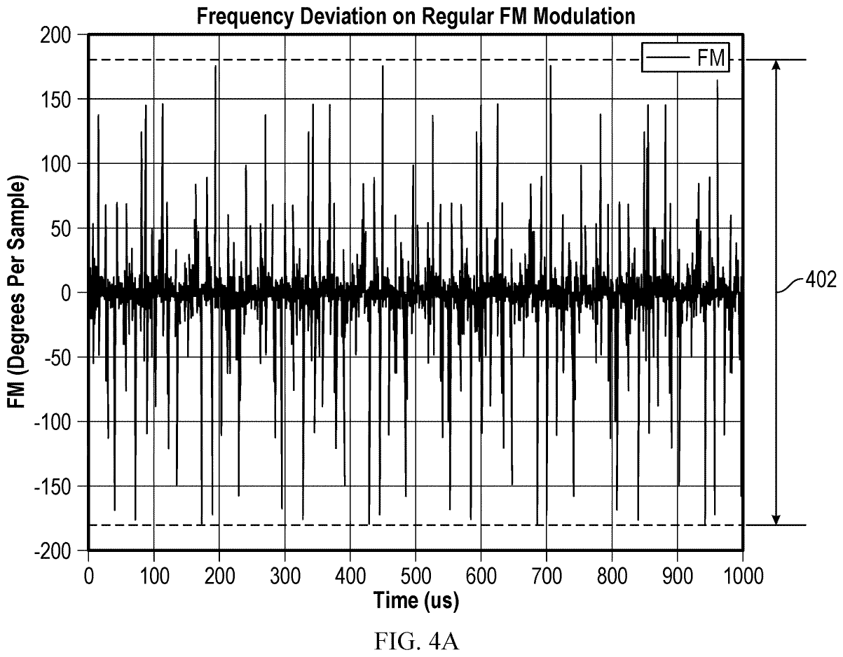

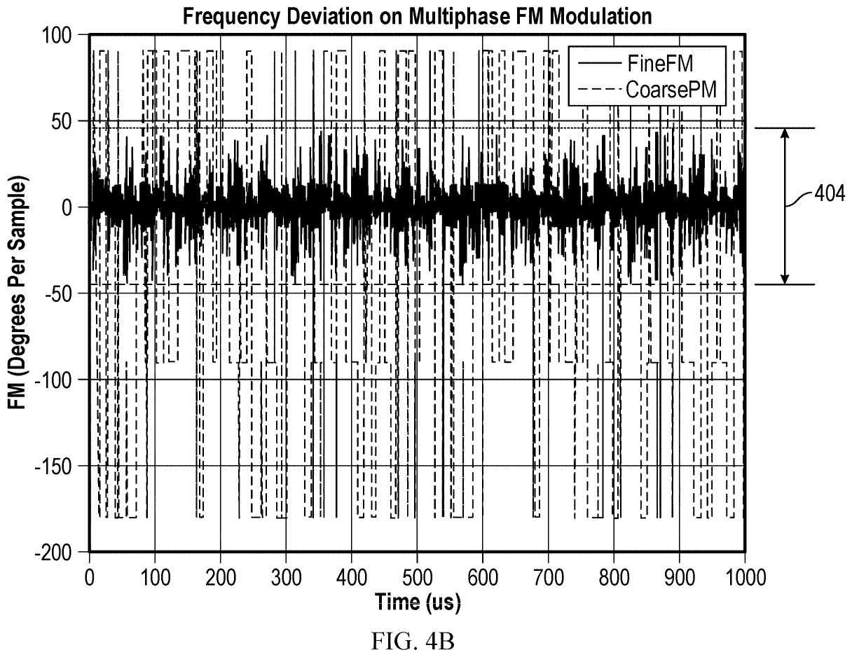

FIG. 4A is a graph illustrating an example of frequency modulations over time using a single frequency modulation. In this example, the frequency modulation generates an effective phase modulation across a range of phases 402 including 0 degrees to 360 degrees (e.g., ±180 degrees from 0 degrees). Performing phase modulation across the range of phases 402 may produce noise in the transmitted radio frequency signal, for example, due to inaccuracies with the control signal of a VCO representing the correct phase of an angular component associated with a constellation point. Moreover, this large phase modulation of ±180 degrees may lead to a more complex MDAC design, one which may have a greater footprint.

FIG. 4B is a graph illustrating an example of frequency modulations over time using multiphase frequency modulation. In this example, the frequency modulation generates an effective phase modulation using a fine phase modulation across a range of phases 404 (e.g., ±180/N degrees) and a coarse phase modulation using a multiphase generator, as described herein with respect to FIG. 2. In such a case, the control signal for the VCO can represent a smaller range of phases 404 compared to the phase modulation performed in relation to FIG. 4A, and as a result, the multiphase frequency modulation may reduce the noise produced from the frequency modulation. For example, the control signal may be able to more accurately represent the angular component associated with the intended constellation point for transmission, with fine tuning of the effective phase modulation performed at the VCO. Furthermore, this smaller phase modulation may allow for a simpler MDAC design, one which may have a smaller footprint.

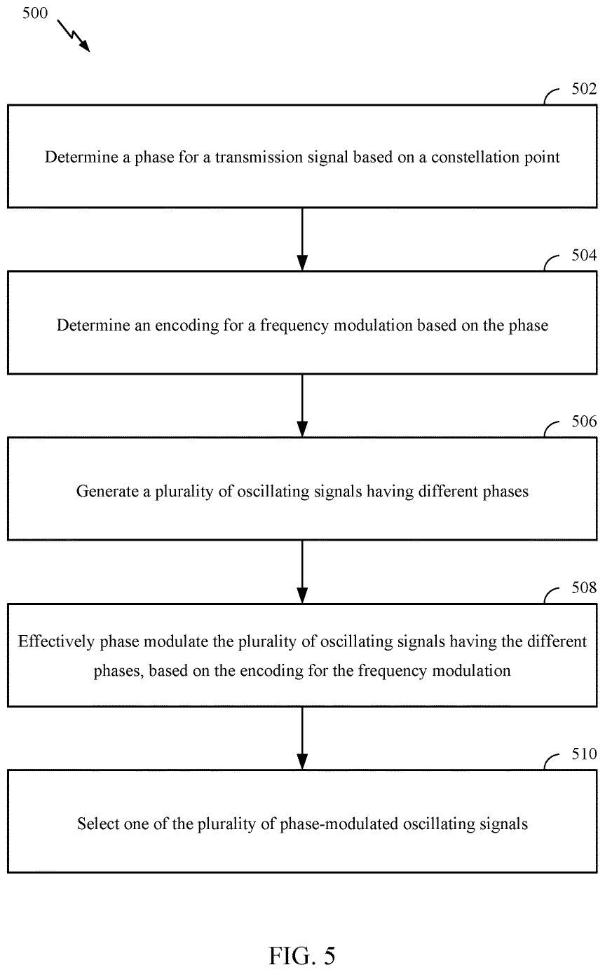

FIG. 5 is a flow diagram of example operations 500 for wireless communication. The operations 500 may be performed by a transmitter, such as the transmitter circuit 200. The operations 500 may be implemented as software components (e.g., computer-executable code or instructions) that are executed and run on one or more processors (e.g., the processor 608 or signal processor 618 of FIG. 6). Further, the transmission of signals by the transmitter in operations 500 may be enabled, for example, by one or more antennas (e.g., the antenna 118 of FIG. 1). In certain aspects, the transmission of signals by the transmitter may be implemented via a bus interface of a circuit (e.g., a radio frequency integrated circuit or) obtaining and/or outputting signals.

The operations 500 may optionally begin at block 502, where the transmitter circuit may determine a phase for a transmission signal based on a constellation point (e.g., the constellation point 302a). For example, the transmitter circuit may determine an angular component (e.g., the angular component 306a) associated with the constellation point and apply the angular component as the phase for the transmission signal as described herein with respect to Expression (1b).

At block 504, the transmitter circuit may determine an encoding for a frequency modulation based on the phase. For example, to determine the encoding for the frequency modulation, the transmitter circuit may generate a fine frequency modulation encoding (e.g., the fine frequency modulation encoding 212) for inputting to a MDAC (e.g., the MDAC 216) or controlling an effective phase modulation, and the transmitter circuit may generate a coarse frequency modulation encoding (e.g., the coarse frequency modulation encoding 214) for controlling a phase modulator (e.g., the phase modulator 224) or selecting an oscillating signal among a plurality of oscillating having different phases. In certain aspects, to determine the encoding for the frequency modulation, the transmitter circuit may differentiate the phase for the transmission signal, for example, to convert the phase to an instantaneous frequency.

At block 506, the transmitter circuit may generate a plurality of oscillating signals having different phases. The transmitter circuit may generate a number (N) of the oscillating signals having the different phases, where the different phases are in increments of (360/N)°, for example, as described herein with respect to FIGS. 2 and 3. To generate the oscillating signals, the transmitter circuit may perform a multistage phase modulation. For example, the transmitter circuit may control a VCO (e.g., the VCO 218) to generate an oscillating signal, and the transmitter circuit may frequency divide the oscillating signal to generate a number (N) of the oscillating signals having the different phases.

At block 508, the transmitter circuit may effectively phase modulate the plurality of oscillating signals having the different phases, based on the encoding for the frequency modulation. The transmitter circuit may effectively phase modulate the plurality of oscillating signals by (±180/N)°. To effectively phase modulate the oscillating signals, the transmitter circuit may maintain a phase separation of (360/N)° between the oscillating signals having the different phases. In certain aspects, the transmitter circuit may use the MDAC to control the VCO to effectively modulate the phase of the oscillating signals by (±180/N)°. The fine frequency modulation encoding may control the effective phase modulation. For example, the fine frequency modulation encoding may indicate the instantaneous frequency to output using the VCO, and the frequency may be converted to a control voltage applied to the control input of the VCO.

At block 510, the transmitter circuit may select one of the plurality of phase-modulated oscillating signals, for example, using the phase modulator. In certain aspects, the coarse frequency modulation encoding may indicate the selection of the oscillating signal among the phase-modulated oscillating signals. The transmitter circuit may select one of the plurality of phase-modulated oscillating signals with a modulated phase nearest the constellation point.

In certain aspects, the transmitter circuit may perform a multistage phase modulation, for example, as described herein with respect to FIG. 2. As an example, in a first phase modulation stage, the transmitter circuit may effectively phase modulate an oscillating signal by ±45°, and in a second phase modulation stage, the transmitter circuit may generate four oscillating signals with phase increments of 90° relative to the oscillating signal.

For certain aspects, the transmitter circuit may amplify the selected one of the plurality of phase-modulated oscillating signals, process the amplified signal (e.g., amplitude modulating, filtering, and/or performing impedance matching on the amplified signal), and transmit the processed signal as the transmission signal, for example, via the antenna 118.

### Example Wireless Communications Network

In certain aspects, the apparatus and methods for multiphase frequency modulation may be used in certain wireless communication devices in a wireless network. FIG. 6 is a diagram of a wireless communication network 600 that includes a wireless communication device 602, which has a wireless transceiver 622 that may include the transmitter circuit 200 of FIG. 2. In certain aspects, the wireless transceiver 622 may be configured to perform the multiphase frequency modulation, for example, as described herein with respect to FIGS. 2-5.

In the wireless communication network 600, the wireless communication device 602 may communicate with other wireless communication devices 604a-604d (e.g., a base station 604a, an access point 604b, wireless headphones 604c, or a cellular phone 604d) through one or more wireless links 606. As shown, the wireless communication device 602 is depicted as a smartphone. However, the wireless communication device 602 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IOT) device, sensor or security device, asset tracker, and so forth. In some cases, the transmitter circuit 200 may be implemented in the other wireless communication devices 604a-604d.

As an example, the base station 604a communicates with the wireless communication device 602 via the wireless link 606, which may be implemented as any suitable type of wireless link. Although depicted as a base station tower of a cellular radio network, the base station 604a may represent or be implemented as another device, such as any of the other wireless communication device 604b-604d, a satellite, terrestrial broadcast tower, access point (e.g., the access point 604b), peer-to-peer device (e.g., the wireless headphones 604c or cellular phone 604d), mesh network node, fiber optic line, another electronic device generally as described above, and so forth. Hence, the wireless communication device 602 may communicate with the base station 604a or another device (e.g., any of the other wireless communication devices 604b-604d) via a wired connection, a wireless connection, or a combination thereof. The wireless link 606 can include a downlink of data or control information communicated from the base station 604a to the wireless communication device 602 and an uplink of other data or control information communicated from the wireless communication device 602 to the base station 604a. The wireless link 606 may be implemented using any suitable communication protocol or standard, such as 3rd Generation Partnership Project Long-Term Evolution (3GPP LTE), 3GPP New Radio Fifth Generation (NR 5G), IEEE 802.11 (WiFi), IEEE 802.16 (WiMAX), Bluetooth™, and so forth.

The wireless communication device 602 includes a processor 608 and a memory 610. The memory 610 may be or form a portion of a computer-readable storage medium. The processor 608 may include any type of processor, such as an application processor or a multi-core processor, that is configured to execute processor-executable instructions (e.g., code) stored by the memory 610. The memory 610 is configured to store instructions (e.g., computer-executable code or instructions) that when executed by the processor 608, cause the processor 608 to perform the operations for multiphase frequency modulation such as the operations 500 described with respect to FIG. 5, or any aspect related to such operations. The memory 610 may include any suitable type of data storage media, such as volatile memory (e.g., random access memory (RAM)), non-volatile memory (e.g., flash memory), optical media, magnetic media (e.g., disk or tape), and so forth. In the context of this disclosure, the memory 610 is implemented to store instructions 612, data 614, and other information of the wireless communication device 602, and thus when configured as or part of a computer-readable storage medium, the memory 610 does not include transitory propagating signals or carrier waves. The memory 610 may include non-transitory computer-readable media (e.g., tangible media).

The wireless communication device 602 may also include input/output ports 616. The I/O ports 616 enable data exchanges or interaction with other devices, networks, or users or between components of the device.

The wireless communication device 602 may further include a signal processor (SP) 618 (e.g., such as a digital signal processor (DSP)). The signal processor 618 may function similar to the processor 608 and may be capable of executing instructions and/or processing information in conjunction with the memory 610.

For communication purposes, the wireless communication device 602 also includes a modem 620, a wireless transceiver 622, and an antenna (not shown). The wireless transceiver 622 provides connectivity to respective networks and other wireless communication devices connected therewith using radio-frequency (RF) wireless signals. The wireless transceiver 622 may include the circuitry for multiphase frequency modulation described herein with respect to FIG. 2, such as the transmitter circuit 200. The wireless transceiver 622 may facilitate communication over any suitable type of wireless network, such as a wireless local area network (WLAN), a peer-to-peer (P2P) network, a mesh network, a cellular network, a wireless wide area network (WWAN), a navigational network (e.g., the global positioning system (GPS) of North America or another global navigation satellite system (GNSS)), and/or a wireless personal area network (WPAN).

The various operations of methods described above may be performed by any suitable means capable of performing the corresponding functions. The means may include various hardware and/or software component(s) and/or module(s), including, but not limited to a circuit, an application specific integrated circuit (ASIC), or processor. For example, means for determining may include a modem (e.g., the modem 202), a processor (e.g., the polar processor 102, the CORDIC 204, the processor 608, and/or the signal processor 618), memory (e.g., the memory 610), an AMPM module (e.g., the AMPM module 206), a differentiator (e.g., the differentiator 208), and/or a bit splitter (e.g., the bit splitter 210). Means for generating, phase modulating, selecting, and/or amplifying oscillating signals may include an MDAC (e.g., the MDAC 216), a VCO (e.g., the VCO 218), a multiphase generator (e.g., the multiphase generator 220), a phase modulator (e.g., the phase modulator 224), and/or an amplifier (e.g., the PA 112).

Based on the present disclosure, it should be appreciated that the apparatus and the method for multiphase frequency modulation described herein provide various advantages. The methods and apparatus described herein may improve the wireless communication performance of polar transmitters enabling reduced adjacent channel powers, decreased latencies, and/or increased data rates. The methods and apparatus described herein may reduce the maximum value of frequency modulation adjusted by a DAC, and in some cases, the frequency modulation noise may be reduced by 12 decibels. The reduction in frequency modulation noise may improve the wireless communication performance of the polar transmitter.

### Example Aspects

In addition to the various aspects described above, specific combinations of aspects are within the scope of the disclosure, some of which are detailed below:

Aspect 1: A transmitter circuit for wireless communication, comprising: a voltage-controlled oscillator (VCO) configured to generate an oscillating signal; a modulation digital-to-analog converter (MDAC) having an output coupled to a control input of the VCO and configured to effectively modulate a phase of the oscillating signal; a multiphase generator having an input coupled to an output of the VCO and configured to generate a plurality of oscillating signals having different phases from the phase-modulated oscillating signal; and a phase modulator having inputs coupled to outputs of the multiphase generator and configured to select and output one of the plurality of oscillating signals.

Aspect 2: The transmitter circuit of Aspect 1, wherein the multiphase generator is configured to generate a number (N) of the oscillating signals having the different phases and wherein the different phases are in increments of (360/N)°.

Aspect 3: The transmitter circuit of Aspect 2, wherein the MDAC is configured to control the VCO to effectively modulate the phase of the oscillating signal by (±180/N)°.

Aspect 4: The transmitter circuit according to any of Aspects 1-3, wherein the multiphase generator is configured to generate four oscillating signals with phase increments of 90° and wherein the MDAC is configured to control the VCO to effectively modulate the phase of the oscillating signal by ±45°.

Aspect 5: The transmitter circuit according to any of Aspects 1-4, further comprising a bit splitter having a first output coupled to an input of the MDAC and having a second output coupled to a control input of the phase modulator, wherein the bit splitter is configured to receive an encoding for a frequency modulation and to generate a fine frequency modulation encoding for the MDAC and a coarse frequency modulation encoding for the phase modulator.

Aspect 6: The transmitter circuit of Aspect 5, wherein the coarse frequency modulation encoding is configured to control selection of the one of the plurality of oscillating signals by the phase modulator.

Aspect 7: The transmitter circuit of Aspect 5 or 6, further comprising a differentiator having an output coupled to an input of the bit splitter and configured to receive a phase encoding and to generate the encoding for the frequency modulation based on the phase encoding using differentiation.

Aspect 8: The transmitter circuit according to any of Aspects 1-7, further comprising an amplifier having an input coupled to an output of the phase modulator and configured to amplify the one of the plurality of oscillating signals selected and output by the phase modulator for transmission.

Aspect 9: The transmitter circuit according to any of Aspects 1-9, wherein the multiphase generator comprises a frequency divider.

Aspect 10: A method of wireless communication, comprising: determining a phase for a transmission signal based on a constellation point; determining an encoding for a frequency modulation based on the phase; generating a plurality of oscillating signals having different phases; effectively phase modulating the plurality of oscillating signals having the different phases, based on the encoding for the frequency modulation; and selecting one of the plurality of phase-modulated oscillating signals.

Aspect 11: The method of Aspect 10, wherein the generating comprises generating a number (N) of the oscillating signals having the different phases and wherein the different phases are in increments of (360/N)°.

Aspect 12: The method of Aspect 11, wherein the effectively phase modulating comprises effectively phase modulating the plurality of oscillating signals by (±180/N)°.

Aspect 13: The method of Aspect 11 or 12, wherein the effectively phase modulating comprises maintaining a phase separation of (360/N)° between the oscillating signals having the different phases.

Aspect 14: The method according to any of Aspects 10-13, wherein the generating comprises generating four oscillating signals with phase increments of 90° and wherein the effectively phase modulating comprises effectively phase modulating the plurality of oscillating signals by ±45°.

Aspect 15: The method according to any of Aspects 10-14, wherein the generating comprises: controlling a voltage-controlled oscillator (VCO) to generate an oscillating signal; and frequency dividing the oscillating signal to generate a number (N) of the oscillating signals having the different phases.

Aspect 16: The method of Aspect 15, wherein the effectively phase modulating comprises using a modulation digital-to-analog converter (MDAC) to control the VCO to effectively modulate the phase of the oscillating signal by (±180/N)°.

Aspect 17: The method of Aspect 16, wherein determining the encoding for the frequency modulation comprises: generating a fine frequency modulation encoding for inputting to the MDAC; and generating a coarse frequency modulation encoding for controlling a phase modulator, wherein the selecting comprises using the phase modulator to select the one of the plurality of oscillating signals.

Aspect 18: The method according to any of Aspects 10-16, wherein determining the encoding for the frequency modulation comprises: generating a fine frequency modulation encoding for controlling the effectively phase modulating; and generating a coarse frequency modulation encoding for controlling the selecting.

Aspect 19: The method according to any of Aspects 10-18, wherein determining the encoding for the frequency modulation comprises differentiating the phase for the transmission signal.

Aspect 20: The method according to any of Aspects 10-19, further comprising: amplifying the selected one of the plurality of phase-modulated oscillating signals; processing the amplified signal; and transmitting the processed signal as the transmission signal.

Aspect 21: The method according to any of Aspects 10-20, wherein the selecting comprises selecting the one of the plurality of phase-modulated oscillating signals with a modulated phase nearest the constellation point.

Aspect 22: An apparatus for wireless communication, comprising: means for determining a phase for a transmission signal based on a constellation point; means for determining an encoding for a frequency modulation based on the phase; means for generating a plurality of oscillating signals having different phases; means for effectively phase modulating the plurality of oscillating signals having the different phases, based on the encoding for the frequency modulation; and means for selecting one of the plurality of phase-modulated oscillating signals.

Aspect 23: An apparatus, comprising: a memory comprising computer-executable instructions; one or more processors configured to execute the computer-executable instructions and cause the apparatus to perform a method in accordance with any of Aspects 10-21.

Aspect 24: An apparatus, comprising: circuitry configured to perform a method in accordance with any of Aspects 10-21.

Aspect 25: An apparatus, comprising means for performing a method in accordance with any of Aspects 10-21.

Aspect 26: A non-transitory computer-readable medium comprising computer-executable instructions that, when executed by one or more processors of a processing system, cause the processing system to perform a method in accordance with any of Aspects 10-21.

Aspect 27: A computer program product embodied on a computer-readable storage medium comprising code for performing a method in accordance with any of Aspects 10-21.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a signal may refer to a detectable physical quantity or impulse (such as a voltage, current, or magnetic field strength over time) by which messages or information can be transmitted. A signal may carry information available for observation.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. A transmitter circuit for wireless communication, comprising:
a voltage-controlled oscillator (VCO) configured to generate an oscillating signal;
a modulation digital-to-analog converter (MDAC) having an output coupled to a control input of the VCO and configured to effectively modulate a phase of the oscillating signal;
a multiphase generator having an input coupled to an output of the VCO and configured to generate a plurality of oscillating signals having different phases from the phase-modulated oscillating signal; and
a phase modulator having inputs coupled to outputs of the multiphase generator and configured to select and output one of the plurality of oscillating signals.

2. The transmitter circuit of claim 1, wherein the multiphase generator is configured to generate a number (N) of the oscillating signals having the different phases and wherein the different phases are in increments of (360/N)°.

3. The transmitter circuit of claim 2, wherein the MDAC is configured to control the VCO to effectively modulate the phase of the oscillating signal by (±180/N)°.

4. The transmitter circuit of claim 1, wherein the multiphase generator is configured to generate four oscillating signals with phase increments of 90° and wherein the MDAC is configured to control the VCO to effectively modulate the phase of the oscillating signal by ±45°.

5. The transmitter circuit of claim 1, further comprising a bit splitter having a first output coupled to an input of the MDAC and having a second output coupled to a control input of the phase modulator, wherein the bit splitter is configured to receive an encoding for a frequency modulation and to generate a fine frequency modulation encoding for the MDAC and a coarse frequency modulation encoding for the phase modulator.

6. The transmitter circuit of claim 5, wherein the coarse frequency modulation encoding is configured to control selection of the one of the plurality of oscillating signals by the phase modulator.

7. The transmitter circuit of claim 5, further comprising a differentiator having an output coupled to an input of the bit splitter and configured to receive a phase encoding and to generate the encoding for the frequency modulation based on the phase encoding using differentiation.

8. The transmitter circuit of claim 1, further comprising an amplifier having an input coupled to an output of the phase modulator and configured to amplify the one of the plurality of oscillating signals selected and output by the phase modulator for transmission.

9. (canceled)

10. A method of wireless communication, comprising:
determining a phase for a transmission signal based on a constellation point;
determining an encoding for a frequency modulation based on the phase;
generating a plurality of oscillating signals having different phases;
effectively phase modulating the plurality of oscillating signals having the different phases, based on the encoding for the frequency modulation; and
selecting one of the plurality of phase-modulated oscillating signals.

11. The method of claim 10, wherein the generating comprises generating a number (N) of the oscillating signals having the different phases and wherein the different phases are in increments of (360/N)°.

12. The method of claim 11, wherein the effectively phase modulating comprises effectively phase modulating the plurality of oscillating signals by (±180/N)°.

13. The method of claim 11, wherein the effectively phase modulating comprises maintaining a phase separation of (360/N)° between the oscillating signals having the different phases.

14. The method of claim 10, wherein the generating comprises generating four oscillating signals with phase increments of 90° and wherein the effectively phase modulating comprises effectively phase modulating the plurality of oscillating signals by ±45°.

15. The method of claim 10, wherein the generating comprises:
controlling a voltage-controlled oscillator (VCO) to generate an oscillating signal; and
frequency dividing the oscillating signal to generate a number (N) of the oscillating signals having the different phases.

16. The method of claim 15, wherein the effectively phase modulating comprises using a modulation digital-to-analog converter (MDAC) to control the VCO to effectively modulate the phase of the oscillating signal by (±180/N)°.

17. The method of claim 16, wherein determining the encoding for the frequency modulation comprises:
generating a fine frequency modulation encoding for inputting to the MDAC; and
generating a coarse frequency modulation encoding for controlling a phase modulator, wherein the selecting comprises using the phase modulator to select the one of the plurality of oscillating signals.

18. The method of claim 10, wherein determining the encoding for the frequency modulation comprises:
generating a fine frequency modulation encoding for controlling the effectively phase modulating; and
generating a coarse frequency modulation encoding for controlling the selecting.

19. (canceled)

20. The method of claim 10, further comprising:
amplifying the selected one of the plurality of phase-modulated oscillating signals;
processing the amplified signal; and
transmitting the processed signal as the transmission signal.

21. The method of claim 10, wherein the selecting comprises selecting the one of the plurality of phase-modulated oscillating signals with a modulated phase nearest the constellation point.

22. An apparatus for wireless communication, comprising:
means for determining a phase for a transmission signal based on a constellation point;
means for determining an encoding for a frequency modulation based on the phase;
means for generating a plurality of oscillating signals having different phases;
means for effectively phase modulating the plurality of oscillating signals having the different phases, based on the encoding for the frequency modulation; and
means for selecting one of the plurality of phase-modulated oscillating signals.
